(19) United States
(12) Patent Application Publication
(10) Pub. No.: US 2025/0313934 A1
(43) Pub. Date: Oct. 9, 2025

(54) DEPOSITION MASK

(71) Applicant: Samsung Display Co., LTD., Yongin-si (KR)

(72) Inventor: Sung Woon KIM, Yongin-si (KR)

(21) Appl. No.: 18/957,894

(22) Filed: Nov. 25, 2024

(30) Foreign Application Priority Data
Apr. 9, 2024 (KR) 10-2024-0047871

(51) Int. Cl. C23C 14/04; H10K 71/16

(52) U.S. Cl. CPC C23C 14/042; H10K 71/166

(57) ABSTRACT

A deposition mask includes a mask substrate including a plurality of cell areas and a cell peripheral area surrounding the cell areas; a mask membrane disposed in the cell areas of the mask substrate and including a mask shadow defining a pixel opening; a mask frame disposed in the cell peripheral area of the mask substrate and including a first upper inorganic layer located on the mask substrate and a second upper inorganic layer located on the first upper inorganic layer; and a mask conductive layer including a first portion located on the mask frame and a second portion located on the mask shadow, where the first portion and the second portion are spaced apart from each other with the pixel opening therebetween.

This application claims priority to Korean Patent Application No. 10-2024-0047871, filed on Apr. 9, 2024, and all the benefits accruing therefrom under 35 U.S.C. § 119, the content of which in its entirety is herein incorporated by reference.

### BACKGROUND

### 1. Field

Embodiments of the disclosure relate to a deposition mask.

### 2. Description of the Related Art

A wearable device, which is in the form of glasses or a helmet and forms a focus at a location close to the user's eyes, is being recently developed. For example, a wearable device may be a head mounted display (HMD) device or an augmented reality (AR) glass. Such a wearable device provides a user with an AR) screen or a virtual reality (VR) screen.

A wearable device such as an HMD device and AR glasses require display specifications of at least 2,000 pixels per inch (PPI) to allow users to use it for a long time without dizziness. Accordingly, organic light-emitting diode on silicon (OLEDoS) technology, which is high-resolution small organic light-emitting element display device, may be used for such a wearable device. The OLEDoS is a technology for disposing organic light-emitting diodes (OLEDs) on a semiconductor wafer substrate on which a complementary metal oxide semiconductor (CMOS) is disposed.

### SUMMARY

Embodiments of the disclosure provide a silicon deposition mask that can fabricate a high-resolution display panel.

Embodiments of the disclosure also provide a deposition mask that can prevent mask damage in use.

It should be noted that embodiments of the disclosure are not limited to those described herein; and other embodiments of the disclosure will be apparent to those skilled in the art from the following descriptions.

In an embodiment of the disclosure, a deposition mask includes a mask substrate including a plurality of cell areas and a cell peripheral area surrounding the cell areas; a mask membrane disposed in the cell areas of the mask substrate and including a mask shadow defining a pixel opening; a mask frame disposed in the cell peripheral area of the mask substrate and including a first upper inorganic layer located on the mask substrate and a second upper inorganic layer located on the first upper inorganic layer; and a mask conductive layer including a first portion located on the mask frame and a second portion located on the mask shadow, where the first portion and the second portion are spaced apart from each other with the pixel opening therebetween.

In an embodiment, a height of the mask conductive layer may be equal to or greater than about 20 nanometers and equal to or less than about 300 nanometers.

In an embodiment, the mask conductive layer may contain a conductive metal material.

In an embodiment, the first portion may completely surround the mask frame, and the second portion of the mask conductive layer completely surrounds the mask shadow.

In an embodiment, the second upper inorganic layer may include a protrusion that protrudes toward the cell areas than a side surface of the first upper inorganic layer, and the first portion may overlap the protrusion of the second upper inorganic layer in a thickness direction of the mask substrate.

In an embodiment, the side surface of the first upper inorganic layer and the protrusion of the second upper inorganic layer may collectively form an undercut.

In an embodiment, the first portion may entirely cover the undercut.

In an embodiment, the first portion may be in contact with the mask substrate, the first upper inorganic layer, and the second upper inorganic layer.

In an embodiment, the second portion may be entirely in contact with the mask shadow.

In an embodiment, the mask frame may further include a first lower inorganic layer located on an opposite side of the mask substrate to the first upper inorganic layer; and a second lower inorganic layer located on the first lower inorganic layer, and the mask conductive layer may be in contact with the first lower inorganic layer and the second lower inorganic layer.

In an embodiment, the first upper inorganic layer and the first lower inorganic layer may include a same material as each other, and the second upper inorganic layer and the second lower inorganic layer may include a same material as each other.

In an embodiment, the mask shadow may include a same material as the second upper inorganic layer.

In an embodiment, a height of the mask shadow may be equal to or greater than about 0.5 micrometers and equal to or less than about 2.5 micrometers.

In an embodiment, the mask substrate may further include an edge surface including an edge of the mask substrate, and the mask conductive layer may further include a third portion overlapping the edge surface.

In an embodiment, the third portion may be spaced apart from the second portion with the pixel opening therebetween.

In an embodiment, the mask shadow may completely surround the pixel opening in a plan view, and the mask frame may completely surround the mask membrane in the plan view.

In an embodiment, the mask substrate may include silicon, and the mask substrate has a circular shape in a plan view.

In an embodiment, the second upper inorganic layer may include a first surface located on an opposite side, which is opposite to a side thereof facing the first upper inorganic layer, and the first portion may be entirely in contact with the first surface of the second upper inorganic layer.

In an embodiment, the first portion may be in contact neither with the first upper inorganic layer nor with the mask substrate.

In an embodiment, the mask shadow may include a second surface facing the mask conductive layer, wherein the second portion may be entirely in contact with the second surface of the mask shadow, and the second portion may be not in contact with a side surface of the mask shadow facing the pixel opening.

In an embodiment, an electronic device includes a display device including a display panel formed using a deposition mask; a mask substrate comprising a plurality of cell areas and a cell peripheral area surrounding the cell areas; a mask membrane disposed in the cell areas of the mask substrate and comprising a mask shadow defining a pixel opening; a mask frame disposed in the cell peripheral area of the mask substrate and comprising a first upper inorganic layer located on the mask substrate and a second upper inorganic layer located on the first upper inorganic layer; and a mask conductive layer comprising a first portion located on the mask frame and a second portion located on the mask shadow, wherein the first portion and the second portion are spaced apart from each other with the pixel opening therebetween.

According to embodiments of the disclosure, a deposition mask can be used to fabricate a high-resolution display panel. In such embodiments, a deposition mask according to an embodiment includes a mask conductive layer that covers a mask substrate and a mask membrane, so that it is possible to effectively prevent mask damage defects that may occur in use from occurring.

It would be understood that effects of embodiments of the disclosure are not limited to those described above and other effects of embodiments of the disclosure will be apparent to those skilled in the art from the following descriptions.

### BRIEF DESCRIPTION OF THE DRAWINGS

The above and other features of the disclosure will become more apparent by describing in detail embodiments thereof with reference to the accompanying drawings, in which:

FIG. 1 is a perspective view showing a head-mounted electronic device according to an embodiment of the disclosure.

FIG. 2 is an exploded perspective view showing an example of the head-mounted electronic device of FIG. 1.

FIG. 3 is a perspective view showing a head-mounted electronic device according to an embodiment of the disclosure.

FIG. 4 is an exploded perspective view showing a display device according to an embodiment of the disclosure.

FIG. 5 is a cross-sectional view showing an example of a part of a display panel according to an embodiment of the disclosure.

FIG. 6 is a plan view of a mask according to an embodiment of the disclosure.

FIG. 7 is an enlarged plan view of area A of FIG. 6.

FIG. 8 is a cross-sectional view taken along line X1-X1′ of FIG. 7.

FIG. 9 is an enlarged cross-sectional view of area T of FIG. 8.

FIG. 10 is a cross-sectional view of another example, taken along line X1-X1′ of FIG. 6.

FIG. 11 is an enlarged cross-sectional view of area Q of FIG. 10.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

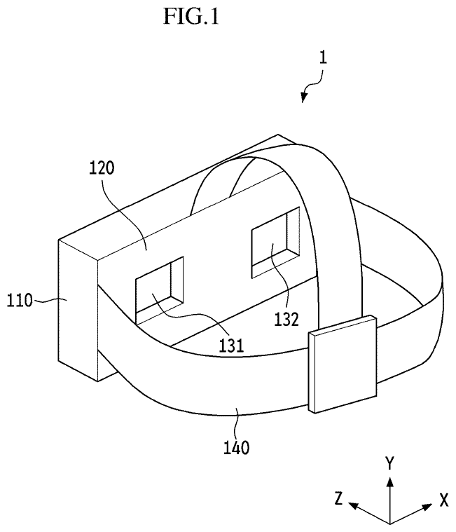

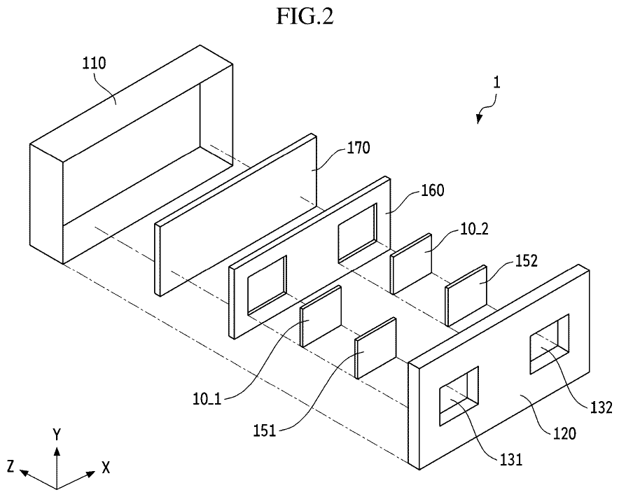

FIG. 1 is a perspective view showing a head-mounted electronic device 1 according to an embodiment. FIG. 2 is an exploded perspective view of an example of the head-mounted electronic device of FIG. 1.

Referring to FIGS. 1 and 2, the head-mounted electronic device 1 according to an embodiment includes a display device housing 110, a housing cover 120, a first eyepiece 131, a second eyepiece 132, a head strap band 140, a first display device 10_1, a second display device 102, a middle frame 160, a first optical member 151, a second optical member 152, a control circuit board 170, and a connector.

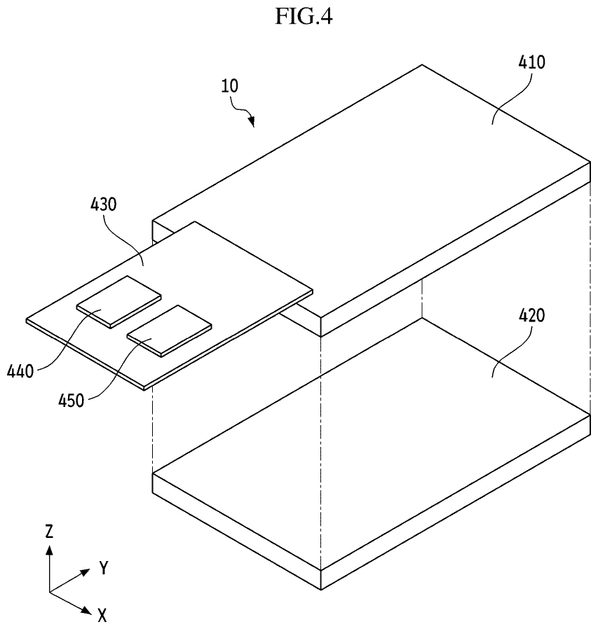

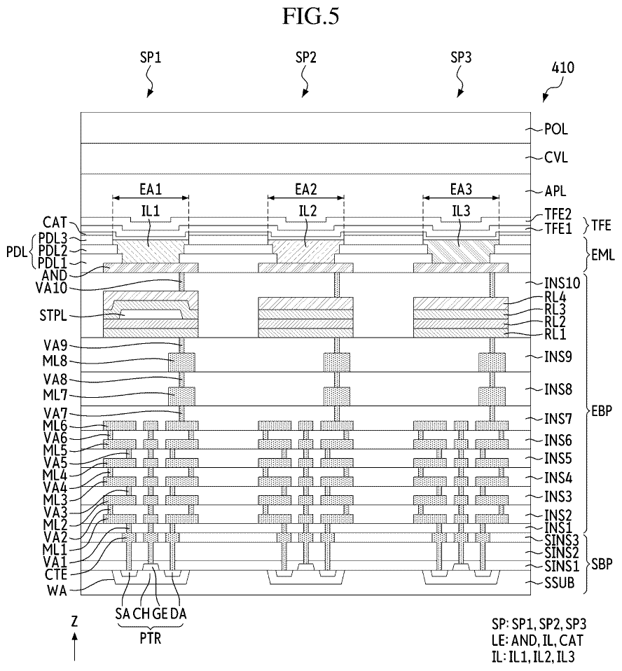

The first display device 101 provides images to a user's left eye, and the second display device 102 provides images to the user's right eye. Each of the first display device 10_1 and the second display device 10_2 is substantially identical to the display device 10 described with reference to FIGS. 4 and 5. Therefore, detailed features of the first display device 10_1 and the second display device 10_2 will be described later referring to FIGS. 4 and 5.

In an embodiment, as shown in FIG. 2, the first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 may support and fix the first display device 101, the second display device 10_2 and the control circuit board 170.

The control circuit board 170 may be disposed between the middle frame 160 and the display device housing 110. The control circuit board 170 may be connected to the first display device 10_1 and the second display device 10_2 through a connector. The control circuit board 170 may convert an image source input from the outside into digital video data and may transmit the digital video data to the first display device 10_1 and the second display device 10_2 through the connector.

In an embodiment, the control circuit board 170 may transmit digital video data associated with a left eye image optimized for the user's left eye to the first display device 10_1, and may transmit digital video data associated with a right eye image optimized for the user's right eye to the second display device 10_2. Alternatively, the control circuit board 170 may transmit the same digital video data to the first display device 10_1 and the second display device 10_2.

The display device housing 110 accommodates the first display device 10_1, the second display device 102, the middle frame 160, the first optical member 151, the second optical member 152, the control circuit board 170, and the connector. The housing cover 120 is disposed to cover an open surface of the housing 110. The housing cover 120 may include the first eyepiece 131 where the user's left eye is placed, and the second eyepiece 132 where the user's right eye is placed. In an embodiment, the first eyepiece 131 and the second eyepiece 132 may be separately disposed as shown in FIGS. 1 and 2, but the embodiments of the present disclosure are not limited thereto. In another embodiment, the first eyepiece 131 and the second eyepiece 132 may be combined into a single element.

The first eyepiece 131 may be aligned with the first display device 10_1 and the first optical member 151, and the second eyepiece 132 may be aligned with the second display device 10_2 and the second optical member 152. Therefore, a user may see virtual images of images on the first display device 10_1 magnified by the first optical member 151 through the first eyepiece 131, and virtual images of images on the second display device 10_2 magnified by the second optical member 152 through the second eyepiece 132.

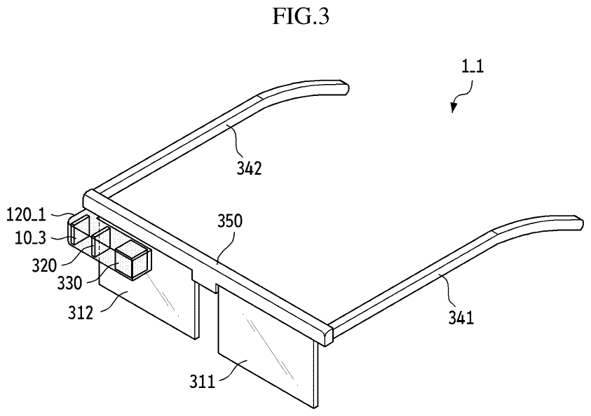

In an embodiment, the head strap band 140 fixes the housing 110 to the user's head so that the first eyepiece 131 and the second eyepiece 132 of the housing cover 120 remain in line with the user's left and right eyes, respectively. In an embodiment, by implementing a light and small display device housing 110, the head-mounted electronic device 1 may include an eyeglasses frame instead of a head strap band 140 as shown in FIG. 3.

In an embodiment, the head-mounted electronic device 1 may further include a battery for supplying power, an external memory slot for inserting an external memory, and an external connection port and a wireless communication module for receiving an image source. The external connection port may be a universe serial bus (USB) terminal, a display port, or a high-definition multimedia interface (HDMI) terminal. The wireless communication module may be a 5G communication module, a 4G communication module, a Wi-Fi module, or a Bluetooth module.

FIG. 3 is a perspective view showing a head-mounted electronic device 1_1 according to an embodiment.

Referring to FIG. 3, the head-mounted electronic device 1_1 according to an embodiment may be a glasses-type display device with a light and small display device housing 1201. The head-mounted electronic device 1_1 according to an embodiment may include a display device 10_3, a left-eye lens 311, a right-eye lens 312, a support frame 350, eyeglass temples 341 and 342, an optical member 320, an optical path conversion member 330, and a display device housing 120_1.

The display device 10_3 shown in FIG. 3 is substantially to the same as the display device 10 described with reference to FIGS. 4 and 5. Therefore, any repetitive detailed descriptions of the first display device 10_1 and the second display device 10_2 will be omitted or simplified.

In an embodiment, the display device housing 120_1 may include the display device 10_3, the optical member 320, and the optical path conversion member 330. The images displayed on the display device 103 may be enlarged by the optical member 320, and the optical path of the images are converted by the optical path conversion member 330 to be provided to the user's right eye through the right eye lens 312. As a result, the user can see, with the right eye, augmented reality images that combine virtual images displayed on the display device 10_3 and real-world images viewed through the right eye lens 312.

In an embodiment, the display device housing 1201 may be disposed at the right end of the support frame 350 as shown in FIG. 3, but the embodiments of the present disclosure are not limited thereto. In an embodiment, for example, the display device housing 120_1 may be disposed at the left end of the support frame 350. In such an embodiment, images displayed on the display device 103 may be provided to the user's left eye. Alternatively, the display device housing 1201 may be disposed at both the left and right ends of the support frame 350, respectively. In such an embodiment, the user can watch images displayed on the display device 10_3 through both the left and right eyes.

FIG. 4 is an exploded perspective view showing a display device 10 according to an embodiment of the disclosure.

Referring to FIG. 4, the display device 10 according to an embodiment displays moving images or still images. The display device 10 according to an embodiment may be employed by portable electronic devices such as a mobile phone, a smart phone, a tablet personal computer (PC), a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IoT). Alternatively, the display device 10 may be applied to a smart watch, a watch phone, or a head-mounted display (HMD) for implementing virtual reality and augmented reality.

According to an embodiment, the display device 10 includes a display panel 410, a heat dissipation layer 420, a circuit board 430, a driver circuit 440, and a power supply circuit 450.

The display panel 410 may have a shape similarly to a rectangular shape in a plan view or when viewed in a thickness direction thereof. In an embodiment, for example, the display panel 410 may have a shape similar to a rectangle having shorter sides in a first direction (X-axis direction) and longer sides in a second direction (Y-axis direction) intersecting the first direction (X-axis direction) in the plan view. Here, a third direction (Y-axis direction) may be a direction perpendicular to the first direction and the second direction, or may be the thickness direction of the display panel 410. In the display panel 410, each of the corners where the shorter side in the first direction (X-axis direction) meets the longer side in the second direction (Y-axis direction) may be rounded with a predetermined curvature or may be a right angle. The shape of the display panel 410 in the plan view is not limited to a rectangular shape, but may be formed in a shape similar to other polygonal shapes, a circular shape, or an elliptical shape. The shape of the display device 10 may follow the shape of the display panel 410 in the plan view, but the embodiments of the disclosure are not limited thereto.

The display panel 410 includes a display area where images are displayed, and a non-display area where no image is displayed.

The display area includes a plurality of pixels, and each of the plurality of pixels includes a plurality of sub-pixels SP1, SP2 and SP3 (see FIG. 5). The sub-pixels SP1, SP2 and SP3 include a plurality of pixel transistors. The pixel transistors are formed via a semiconductor process and may be disposed on a semiconductor substrate SSUB (see FIG. 5). In an embodiment, for example, the pixel transistors may be implemented as complementary metal oxide semiconductor (CMOS).

The heat dissipation layer 420 may overlap the display panel 410 in the third direction (Z-axis direction), which is the thickness direction of the display panel 410. The heat dissipation layer 420 may be disposed on one surface of the display panel 410, e.g., on the rear surface. The heat dissipation layer 420 serves to release heat generated in the display panel 410. The heat dissipation layer 420 may include a metal layer such as graphite, silver (Ag), copper (Cu) and aluminum (Al) having a high thermal conductivity.

The circuit board 430 may be electrically connected to a plurality of pads PD in a pad area PDA of the display panel 410 using a conductive adhesive member such as an anisotropic conductive film. The circuit board 430 may be a flexible printed circuit board made of a flexible material, or a flexible film. In an embodiment, the circuit board 430 may be unfolded as shown in FIG. 4, or the circuit board 430 may be bent. In an embodiment where the circuit board 430 is bent, one end of the circuit board 430 may be disposed on the rear surface of the display panel 410. The one end of the circuit board 430 may be opposite to the opposite end of the circuit board 430, which is connected to the pads PD in the pad area PDA of the display panel 410 using a conductive adhesive member.

The driver circuit 440 may receive digital video data and timing signals from the outside. The driver circuit 440 may generate a scan timing control signal, an emission timing control signal, and a data timing control signal for controlling the display panel 410 in response to the timing signals.

A power supply circuit 450 may generate a plurality of panel driving voltages in response to a supply voltage from the outside.

Each of the driver circuit 440 and the power supply circuit 450 may be implemented as an integrated circuit (IC) and attached to a surface of the circuit board 430.

FIG. 5 is a cross-sectional view showing an example of a part of a display panel 410 according to an embodiment of the disclosure. For example, FIG. 5 shows a cross-sectional structure of a part of a display area that includes a plurality of sub-pixels SP1, SP2 and SP3 (see FIG. 5).

Referring to FIG. 5, an embodiment of the display panel 410 includes a semiconductor backplane SBP, an emission material backplane EBP, an emission material layer EML, an encapsulation layer TFE, an optical layer OPL, and a cover layer CVL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE that are electrically connected to the pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well areas WA may be located in the upper surface of the semiconductor substrate SSUB. The well areas WA may be doped with second-type impurities. The second-type impurities may be different from the first-type impurities. In an embodiment, for example, where the first-type impurities are p-type impurities, the second-type impurities may be n-type impurities. Alternatively, where the first-type impurities are n-type impurities, the second-type impurities may be p-type impurities.

In another embodiment, the semiconductor substrate SSUB may be replaced with a glass substrate or a polymer resin substrate such as polyimide. In such an embodiment, thin-film transistors may be disposed on a glass substrate or a polymer resin substrate. The glass substrate may be a rigid substrate that is not bent, while the polymer resin substrate may be a flexible substrate that can be bent or curved.

Each of the well areas WA includes a source region SA associated with a source electrode of a pixel transistor PTR, a drain region DA associated with a drain electrode thereof, and a channel region CH between the source region SA and the drain region DA.

Each of the source region SA and the drain region DA may be doped with the first-type impurities. The gate electrode GE of the pixel transistor PTR may overlap the well area WA in the third direction (Z-axis direction). The channel region CH may overlap with the gate electrode GE in the third direction (Z-axis direction). The source area SA may be located on one side of the gate electrode GE, and the drain area SA may be located on the opposite side of the gate electrode GE.

A first semiconductor insulating film SINS1 may be disposed on the semiconductor substrate SSUB. The first semiconductor insulating film SINS1 may include or be formed of, but is not limited to, a silicon carbon nitride (SiCN) or a silicon oxide (SiOx)-based inorganic film.

A second semiconductor insulating film SINS2 may be disposed on the first semiconductor insulating film SINS1. The second semiconductor insulating film SINS2 may include or be formed of a silicon oxide (SiOx)-based inorganic film, but the embodiments of the present disclosure are not limited thereto.

A plurality of contact terminals CTE may be disposed on the second semiconductor insulating film SINS2. Each of the plurality of contact terminals CTE may be connected to one of the gate electrode GE, the region SA and the drain region DA of each of the pixel transistors PTR through a hole defined or formed through the first semiconductor insulating film SINS1 and the second semiconductor insulating film SINS2. The contact terminals CTE may include or be made of at least one selected from copper (Cu), aluminum (Al), tungsten (W), molybdenum (Mo), chromium (Cr), gold (Au), titanium (Ti), nickel (Ni) and neodymium (Nd), or an alloy containing one of these.

A third semiconductor insulating film SINS3 may be disposed on the side surface of each of the contact terminals CTE. The upper surface of each of the contact terminals CTE may not be covered by the third semiconductor insulating film SINS3 but may be exposed. In an embodiment, the third semiconductor insulating film SINS3 may include or be formed of a silicon oxide (SiOx)-based inorganic film, but the embodiments of the disclosure are not limited thereto.

The emission material backplane EBP includes first to eighth metal layers ML1 to ML8, reflective metal layers RL1 to RL4, a plurality of vias VA1 to VA10, and a step layer STPL. In addition, the emission material backplane EBP includes a plurality of interlayer dielectric films INS1 to INS10 disposed between the first to sixth metal layers ML1 to ML6.

The first to eighth metal layers ML1 to ML8 serve to implement a circuit of a sub-pixel SP by connecting a plurality of contact terminals CTE exposed from the semiconductor backplane SBP.

The first interlayer dielectric film INS1 may be disposed on the semiconductor backplane SBP. Each of the first vias VA1 may penetrate or extend through the first interlayer dielectric film INS1 and may be connected to the contact terminal CTE exposed from the semiconductor backplane SBP. Each of the first metal layers ML1 may be disposed on the first interlayer insulating film INS1 and may be connected to the first via VA1.

The second interlayer dielectric film INS2 may be disposed on the first interlayer dielectric film INS1 and the first metal layers ML1. Each of the second vias VA2 may penetrate or extend through the second interlayer dielectric film INS2 to be connected to the exposed first metal layer ML1. Each of the second metal layers ML2 may be disposed on the second interlayer insulating film INS2 and may be connected to the second via VA2.

The third interlayer dielectric film INS3 may be disposed on the second interlayer dielectric film INS2 and the second metal layers ML2. Each of the third vias VA3 may penetrate or extend through the third interlayer dielectric film INS3 to be connected to the exposed second metal layer ML2. Each of the third metal layers ML3 may be disposed on the third interlayer insulating film INS3 and may be connected to the third via VA3.

The fourth interlayer dielectric film INS4 may be disposed on the third interlayer dielectric film INS3 and the third metal layers ML3. Each of the fourth vias VA2 may penetrate or extend through the fourth interlayer dielectric film INS4 to be connected to the exposed third metal layer ML3. Each of the fourth metal layers ML4 may be disposed on the fourth interlayer insulating film INS4 and may be connected to the fourth via VA4.

The fifth interlayer dielectric film INS5 may be disposed on the fourth interlayer dielectric film INS4 and the fourth metal layers ML4. Each of the fifth vias VA5 may penetrate or extend through the fifth interlayer dielectric film INS5 to be connected to the exposed fourth metal layer ML4. Each of the fifth metal layers ML5 may be disposed on the fifth interlayer insulating film INS5 and may be connected to the fifth via VA5.

The sixth interlayer dielectric film INS6 may be disposed on the fifth interlayer dielectric film INS5 and the fifth metal layers ML5. Each of the sixth vias VA6 may penetrate or extend through the sixth interlayer dielectric film INS6 to be connected to the exposed fifth metal layer ML5. Each of the sixth metal layers ML6 may be disposed on the sixth interlayer insulating film INS6 and may be connected to the sixth via VA6.

The seventh interlayer dielectric film INS7 may be disposed on the sixth interlayer dielectric film INS6 and the sixth metal layers ML6. Each of the seventh vias VA7 may penetrate or extend through the seventh interlayer dielectric film INS7 to be connected to the exposed sixth metal layer ML6. Each of the seventh metal layers ML7 may be disposed on the seventh interlayer insulating film INS7 and may be connected to the seventh via VA7.

The eighth interlayer dielectric film INS8 may be disposed on the seventh interlayer dielectric film INS7 and the seventh metal layers ML7. Each of the eighth vias VA8 may penetrate or extend through the eighth interlayer dielectric film INS8 to be connected to the exposed seventh metal layer ML7. Each of the eighth metal layers ML8 may be disposed on the eighth interlayer insulating film INS8 and may be connected to the eighth via VA8.

The first to eighth metal layers ML1 to ML8 and the first to eighth vias VA1 to VA8 may include or be made of substantially the same material as each other. In an embodiment, the first to eighth metal layers ML1 to ML8 and the first to eighth vias VA1 to VA8 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy containing one of these. The first to eighth vias VA1 to VA8 may include or be made of substantially the same material as each other. In an embodiment, the first to eighth interlayer dielectric films INS1 to INS8 may include or be formed of a silicon oxide (SiOx)-based inorganic film, but embodiments of the specification are not limited thereto.

The thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6 may be greater than the thickness of the first via VA1, the thickness of the second via VA2, the thickness of the third via VA3, the thickness of the fourth via VA4, the thickness of the fifth via VA5 and the thickness of the sixth via VA6. The thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5 and the thickness of the sixth metal layer ML6 may be substantially all equal.

The thickness of the seventh metal layer ML7 and the thickness of the eighth metal layer ML8 may be greater than the thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6. The thickness of the seventh metal layer ML7 and the thickness of the eighth metal layer ML8 may be greater than the thickness of the seventh via VA7 and the thickness of the eighth via VA8. The thickness of the seventh via VA7 and the thickness of the eighth via VA8 may be greater than the thickness of the first via VA1, the thickness of the second via VA2, the thickness of the third via VA3, and the thickness of the fourth via VA4, the thickness of the fifth via VA5 and the thickness of the sixth via VA6. The thickness of the seventh metal layer ML7 may be substantially equal to the thickness of the eighth metal layer ML8.

The ninth interlayer dielectric film INS9 may be disposed on the eighth interlayer dielectric film INS8 and the eighth metal layers ML8. In an embodiment, the ninth interlayer dielectric film INS9 may include or be formed of a silicon oxide (SiOx)-based inorganic film, but the embodiments of the disclosure are not limited thereto.

Each of the ninth vias VA9 may penetrate or extend through the ninth interlayer dielectric film INS9 to be connected to the exposed eighth metal layer ML8. In an embodiment, the ninth vias VA9 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy containing one of these.

The first reflective electrodes RL1 may be disposed on the ninth interlayer dielectric film INS9 and may be connected to the ninth via VA9. In an embodiment, the first reflective electrodes RL1 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy containing one of these.

The second reflective electrodes RL2 may be disposed on the first reflective electrodes RL1. In an embodiment, the second reflective electrodes RL2 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy containing one of these. In an embodiment, for example, the second reflective electrodes RL2 may include or be formed of titanium nitride (TiN).

In the first sub-pixel SP1, a step layer STPL may be disposed on the second reflective electrode RL2. No step layer STPL may be disposed in each of the second sub-pixel SP2 and the third sub-pixel SP3. The step layer STPL may include or be formed of, but is not limited to, a silicon carbon nitride (SiCN) or a silicon oxide (SiOx)-based inorganic film.

In the first sub-pixel SP1, the third reflective electrode RL3 may be disposed on the second reflective electrode RL2 and the step layer STPL. In the second sub-pixel SP2 and the third sub-pixel SP3, the third reflective electrode RL3 may be disposed on the second reflective electrode RL2. The third reflective electrodes RL3 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy containing one of these. In another embodiment, at least one selected from the first reflective electrode RL1, the second reflective electrode RL2 and the third reflective electrode RL3 may be omitted.

The fourth reflective electrodes RL4 may be disposed on the third reflective electrodes RL3. The fourth reflective electrodes RL4 may include a metal with high reflectivity for light reflection. The fourth reflective electrodes RL4 may include or be formed of, but is not limited to, aluminum (Al), a stack of aluminum and titanium (Ti/Al/Ti), a stack of aluminum and indium tin oxide (ITO) (ITO/Al/ITO), an APC alloy, which is an alloy of silver (Ag), palladium (Pd) and copper (Cu), and a stack of an APC alloy and ITO (ITO/APC/ITO).

The tenth interlayer dielectric film INS10 may be disposed on the ninth interlayer dielectric film INS9 and the fourth reflective electrodes RL4. In an embodiment, the tenth interlayer dielectric film INS10 may include or be formed of a silicon oxide (SiOx)-based inorganic film, but the embodiments of the disclosure are not limited thereto.

Each of the tenth vias VA10 may penetrate or extend through the tenth interlayer dielectric film INS10 to be connected to the exposed ninth metal layer ML9. The tenth vias VA10 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy containing one of these. Due to the step layer STPL, the thickness of the tenth via VA10 in the first sub-pixel SP1 may be smaller than the thickness of the tenth via VA10 in each of the second sub-pixel SP2 and the third sub-pixel SP3.

The emission material layer EML may be disposed on the emission material backplane EBP. The emission material layer EML may include light-emitting elements LE each including a first electrode AND, emissive layers IL and a second electrode CAT, and a pixel-defining layer PDL.

The first electrode AND may be disposed on the tenth interlayer dielectric film INS10 and may be connected to the tenth via VA10. The first electrode AND may be connected to the drain region DA or the source region SA of the pixel transistor PTR through the tenth via VA10, the first to fourth reflective electrodes RL1 to RL4, the first to ninth vias VA1 to VA9, the first to eighth metal layers ML1 to ML8 and the contact terminals CTE. In an embodiment, the first electrode AND may include or be made of at least one selected from copper (Cu), aluminum (Al), tungsten (W), molybdenum (Mo), chromium (Cr), gold (Au), titanium (Ti), nickel (Ni) and neodymium (Nd), or an alloy containing one of these. For example, the first electrode AND may be titanium nitride (TiN).

A pixel-defining layer PDL may be disposed partially on the first electrode AND. The pixel-defining layer PDL may be disposed on edges of the first electrode AND. The pixel-defining layer PDL serves to partition the first emission areas EA1, the second emission areas EA2 and the third emission areas EA3.

A first emission area EA1 may be defined as an area in the first sub-pixel SP1 where a first electrode AND, a first emissive layer IL1 and a second electrode CAT are sequentially stacked on one another to emit light. A second emission area EA2 may be defined as an area in the second sub-pixel SP2 where a first electrode AND, a second emissive layer IL1 and a second electrode CAT are sequentially stacked on one another to emit light. A third emission area EA3 may be defined as an area in the third sub-pixel SP3 where a first electrode AND, a third emissive layer IL3 and a second electrode CAT are sequentially stacked on one another to emit light.

The pixel-defining layer PDL may include first to third pixel-defining layers PDL1, PDL2 and PDL3. The first pixel-defining layer PDL1 may be disposed on the edge of the first electrode AND, the second pixel-defining layer PDL2 may be disposed on the first pixel-defining layer PDL1, and the third pixel-defining layer PDL3 may be disposed on the second pixel-defining layer PDL2. In an embodiment, the first pixel-defining layer PDL1, the second pixel-defining layer PDL2 and the third pixel-defining layer PDL3 may include or be formed of a silicon oxide (SiOx)-based inorganic film, but the embodiments of the disclosure are not limited thereto.

The emissive layers IL may include a first emissive layer IL1, a second emissive layer IL2, and a third emissive layer IL3. The first emissive layer IL1, the second emissive layer IL2 and the third emissive layer IL3 may emit light of different colors or lights having different wavelengths. In an embodiment, for example, the first emissive layer IL1 may emit red light, the second emissive layer IL2 may emit green light, and the third emissive layer IL3 may emit blue light, but the disclosure is not limited thereto.

A plurality of emissive layers IL1, IL2 and IL3 arranged adjacent to each other in the first direction (x-axis direction) may be disconnected by the pixel-defining layer PDL. In the display panel 410 according to an embodiment, it is possible to effectively prevent leakage current between adjacent sub-pixel SP1, SP2 and SP3 and to effectively prevent color crosstalk by disconnecting the first to third emissive layers IL1, IL2 and IL3 arranged adjacent to one another.

The second electrode CAT may be disposed on the emissive layers IL. The second electrode CAT may be a common electrode. The second electrode CAT may include or be formed of a transparent conductive material (TCP) such as ITO and indium zinc oxide (IZO) that can transmit light, or a semi-transmissive conductive material such as magnesium (Mg), silver (Ag) and an alloy of magnesium (Mg) and silver (Ag). In an embodiment where the second electrode CAT is formed of a semi-transmissive conductive material, the light extraction efficiency can be increased by using microcavities in each of the first to third sub-pixels SP1, SP2 and SP3.

The encapsulation layer TFE may be disposed on the emission material layer EML. The encapsulation layer TFE may include at least one inorganic film to prevent permeation of oxygen or moisture into the emission material layer EML. In an embodiment, for example, the encapsulation layer TFE may include a first encapsulation layer TFE1 and a second encapsulation layer TFE2.

The first encapsulation layer TFE1 may be disposed on the second electrode CAT, and the second encapsulation layer TFE2 may be disposed on the first encapsulation layer TFE1. In an embodiment, the first encapsulation layer TFE1 and the second encapsulation layer TFE2 may include or be made up of multiple layers in which one or more inorganic layers of a silicon nitride layer (SiNx), a silicon oxynitride layer (SiON), a silicon oxide layer (SiOx), a titanium oxide layer (TiOx) and an aluminum oxide layer (AlOx) are alternately stacked on one another.

An adhesive layer APL may be a layer provided to increase the interfacial adhesion between the encapsulation layer TFE and the cover layer CVL. The adhesive layer APL may include or be formed of an acryl resin, an epoxy resin, a phenolic resin, a polyamide resin or a polyimide resin.

The cover layer CVL may be disposed on the adhesive layer APL. The cover layer CVL may be a glass substrate or a polymer resin such as a resin. In an embodiment where the cover layer CVL is a glass substrate, the cover layer CVL may work as an encapsulation substrate. In an embodiment where the cover layer CVL is a polymer resin such as resin, the cover layer CVL may be applied or formed directly on the adhesive layer APL.

A polarizer POL may be disposed on a surface of the cover layer CVL. The polarizer POL may be a structure for preventing deterioration of visibility due to reflection of external light. The polarizer POL may include a linear polarizer and a retardation film. In an embodiment, for example, the retardation film may be a λ/4 plate (quarter-wave plate), but the embodiments of the disclosure are not limited thereto.

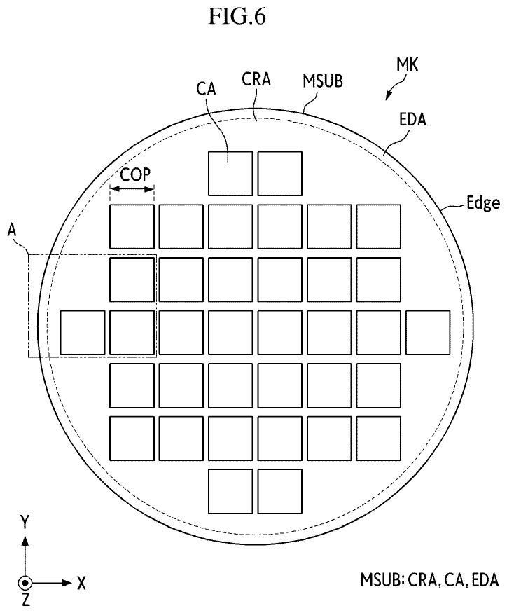

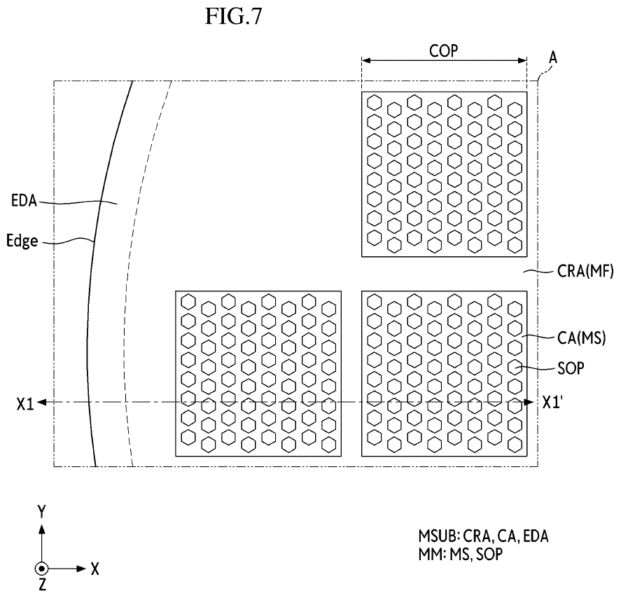

FIG. 6 is a plan view of a mask according to an embodiment of the present disclosure. FIG. 7 is an enlarged plan view of area A of FIG. 6. The mask shown in FIG. 6 may be used in a process of depositing at least some of the emissive layers IL of the display panel 410 described above with reference to FIG. 5.

Referring to FIGS. 6 and 7, the mask MK according to an embodiment may be a mask used to fabricate ultra-high resolution displays. In an embodiment, for example, the mask MK may be a mask used to fabricate a display included in extended reality devices (XR devices) such as a VR device, an AR device and a mixed reality (MR) device.

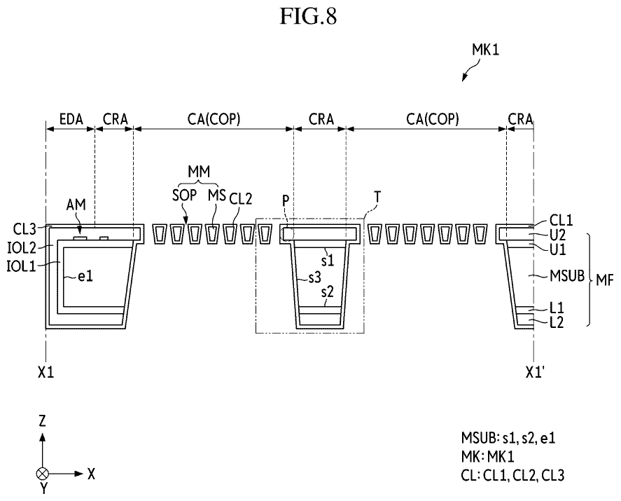

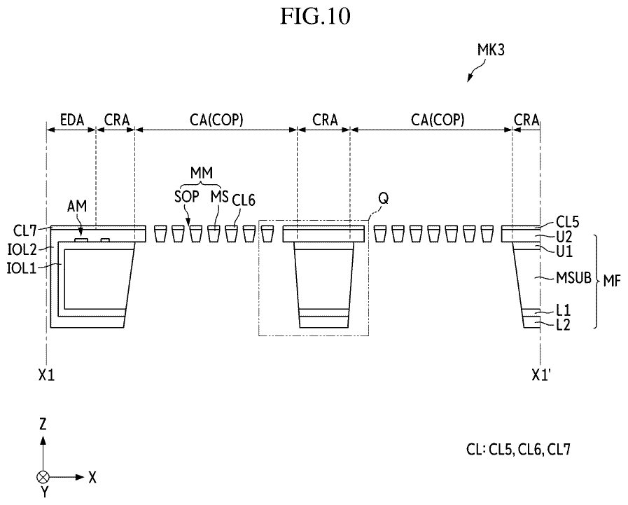

The mask MK according to an embodiment may be used to perform a deposition process of sub-pixels (the sub-pixels SP1, SP2 SP3 in FIG. 5) on a silicon wafer rather than a large-area substrate used for existing displays. For a display included in an extended reality device, the screen is located directly in front of the user's eyes, and thus such a display may have a small screen rather than a large screen. In addition, because the display included in an extended reality device is located close to the user's eyes, ultra-high resolution may be desired. In an embodiment, for example, the desired resolution of a display included in an extended reality device may be about 1,000 pixels per inch (PPI) or greater, e.g., an ultra-high resolution of 2,000 PPI or greater. Accordingly, the deposition mask MK according to an embodiment may be a mask used to fabricate such ultra-high resolution displays. The mask MK according to embodiments of the disclosure may include both an embodiment of a mask MK1 shown in FIG. 8 and another embodiment of a mask MK3 shown in FIG. 10, which will be described later.

The mask MK according to an embodiment may include a mask substrate MSUB.

The mask substrate MSUB according to an embodiment may include a silicon wafer. Silicon wafers may be used as substrates for ultra-high resolution displays because silicon wafers allow finer and more precise processing by utilizing the technologies developed in semiconductor processing than large-area substrates. The mask MK according to an embodiment may use a silicon wafer in the same manner to form pixels on the silicon wafer of such an ultra-high resolution display.

The shape of the mask substrate MSUB according to an embodiment may conform to a silicon wafer of an ultra-high resolution display. In an embodiment, for example, the mask substrate MSUB may have a same size or shape as the silicon wafer of the ultra-high resolution display. It would be understood, however, that the embodiments of the disclosure are not limited thereto. The mask substrate MSUB may include a large-area substrate. In an embodiment, for example, the mask substrate MSUB may include a material such as glass, quartz and polymer resin.

The mask substrate MSUB according to an embodiment may include a plurality of cell areas CA, a cell peripheral area CRA, and an edge area EDA.

The cell peripheral area CRA according to an embodiment may surround the plurality of cell areas CA. The cell peripheral area CRA may correspond to a mask frame MF in a plan view or when viewed in a thickness direction of the mask MK. The mask frame MF may be an area that supports the mask MK. The mask frame MF may define mask openings COP in the plan view, and the mask frame MF may surround the mask openings COP. The mask openings COP may be located to correspond to or to overlap the cell areas CA.

According to an embodiment of the disclosure, a plurality of cell areas CA may be formed, and the cell areas CA may be spaced apart from one another. The cell areas CA may overlap a mask membrane MM. The mask membrane MM may include pixel openings SOP and mask shadows MS. In the plan view, the mask shadows MS may completely surround the pixel openings SOP and may be integrally formed as a single unitary indivisible body.

In the plan view, the mask frame MF may entirely surround the mask shadows MS and may be integrally formed as a single unitary indivisible body. In other words, the mask shadows MS may be in the form of an integrated pattern that exposes the pixel openings SOP in the plan view, and the mask frame MF may be in the form of an integrated pattern that exposes the mask openings COP in the plan view.

The edge area EDA according to an embodiment may refer to the edge of the mask substrate MSUB and the area near the edge. In other words, the edge area EDA may mean the border area of the mask substrate MSUB.

FIG. 8 is a cross-sectional view taken along line X1-X1′ of FIG. 7.

In the cross-sectional view of FIG. 8, the mask frame MF according to an embodiment of the disclosure may be located corresponding to or to overlap the cell peripheral area CRA. The mask frame MF may include a mask substrate MSUB, a first upper inorganic layer U1, a second upper inorganic layer U2, a first lower inorganic layer L1, and a second lower inorganic layer L2.

In some embodiments, the mask substrate MSUB may include a top surface s1, a bottom surface s2, and a side surface s3. The top surface s1 may face the first upper inorganic layer U1, the bottom surface s2 may be opposed to the top surface s1, and the side surface s3 may connect the top surface s1 with the bottom surface s2. The side surface s3 of the mask substrate MSUB may be an inclined surface. Such a structure may be formed by removing a part of the mask substrate MSUB via an etching process during the process of fabricating the mask MK.

In some embodiments, the mask substrate MSUB may further include an edge surface e1 in the edge area EDA. The edge surface e1 may refer to a surface including the edge of the mask substrate MSUB.

According to an embodiment of the disclosure, the first upper inorganic layer U1 may be located on the mask substrate MSUB. The first upper inorganic layer U1 may be in contact with the top surface s1 of the mask substrate MSUB and may entirely cover the top surface s1. The first upper inorganic layer U1 may define the mask openings COP. In cross-section, the mask openings COP may be in line with (correspond to or overlap) the cell areas CA.

The first upper inorganic layer U1 may include an inorganic insulating material. In an embodiment, for example, the first upper inorganic layer U1 may include, but is not limited to, silicon oxide.

According to an embodiment of the disclosure, the second upper inorganic layer U2 may be located on the first upper inorganic layer U1. The second upper inorganic layer U2 may be in contact with the first upper inorganic layer U1 and may entirely cover the first upper inorganic layer U1.

According to an embodiment of the disclosure, the second upper inorganic layer U2 may include a protrusion P that protrudes toward the cell area CA from the side surface s3 of the mask substrate MSUB. The protrusion P of the second upper inorganic layer U2 may protrude in the first direction (X-axis direction) more than the side surface s3 of the mask substrate MSUB.

The second upper inorganic layer U1 may include an inorganic insulating material. In an embodiment, for example, the second upper inorganic layer U2 may include, but is not limited to, silicon nitride.

According to an embodiment of the disclosure, the first upper inorganic layer U1 and the second upper inorganic layer U2 may have different stress properties. In an embodiment, for example, where the first upper inorganic layer U1 includes an inorganic insulating material having compressive stress, the second upper inorganic layer U2 may include an inorganic insulating material having tensile stress. According to an embodiment of the disclosure, as the first upper inorganic layer U1 and the second upper inorganic layer U2 may have different stress properties from each other, it is possible to adjust the stress of the mask MK.

The second upper inorganic layer U2 may include a same material as the mask shadows MS, which will be described later. More detailed descriptions thereof will be given below.

According to an embodiment of the disclosure, the first lower inorganic layer L1 may be located on the bottom surface s2 of the mask substrate MSUB. The first lower inorganic layer L1 may be in contact with the bottom surface s2 and may entirely cover the bottom surface s2.

During the process of fabricating the mask MK, the first mask inorganic layer IOL1 may be formed to entirely cover the top surface s1, the bottom surface s2, and the edge surface e1 of the mask substrate MSUB. Then, a part of the first mask inorganic layer IOL1 may be removed via a subsequent etching process, thereby forming the first upper inorganic layer U1 and the first lower inorganic layer L1 as shown in the drawings.

In this process, a part of the first mask inorganic layer IOL1 that has not been removed from the edge area EDA and the area around it may remain to cover the top surface s1, the bottom surface s2 and the edge surface e1 of the mask substrate MSUB. It would be understood, however, that the embodiments of the disclosure are not limited thereto. In another embodiment, the first mask inorganic layer IOL1 located in the edge area EDA may be removed depending on fabrication processes. In other words, the first lower inorganic layer L1 and the first upper inorganic layer U1 may be parts of the first mask inorganic layer IOL1 during the fabrication process and then formed as shown in the drawings.

Accordingly, the first lower inorganic layer L1 located in the cell peripheral area CRA may include a same material as the first upper inorganic layer U1. Depending on embodiments, the first mask inorganic layer IOL1 may be described as the first lower inorganic layer L1 or the first upper inorganic layer U1.

According to an embodiment of the disclosure, an alignment mark AM may be located on the first mask inorganic material layer IOL1 in the edge area EDA and the area near the edge area EDA. The alignment mark AM may be formed to align the display panel 410 shown in FIG. 5 with the mask MK. The shape of the alignment mark AM is not limited to that shown in the drawings, but the alignment mark AM may have various shapes and arrangements.

According to an embodiment of the disclosure, the second lower inorganic layer L2 may be located on the first lower inorganic layer L1. The second lower inorganic layer L2 may be in contact with the first lower inorganic layer L1.

During the process of fabricating the mask MK, the second mask inorganic layer IOL2 may be formed to entirely cover the top surface s1, the bottom surface s2, and the edge surface e1 of the mask substrate MSUB. Then, a part of the second mask inorganic layer IOL2 may be removed via a subsequent etching process, thereby forming the second upper inorganic layer U2 and the second lower inorganic layer L2 as shown in the drawings.

In this process, a part of the second mask inorganic layer IOL2 that has not been removed from the edge area EDA and the area around it may remain to cover the top surface s1, the bottom surface s2 and the edge surface e1 of the mask substrate MSUB. It would be understood, however, that the embodiments of the present disclosure are not limited thereto. In another embodiment, the second mask inorganic layer IOL2 located in the edge area EDA may be removed depending on fabrication processes. In other words, the second lower inorganic layer L2 and the second upper inorganic layer U2 may be parts of the second mask inorganic layer IOL2 during the fabrication process and then formed as shown in the drawings.

Accordingly, the second lower inorganic layer L2 located in the cell peripheral area CRA may include a same material as the second upper inorganic layer U2. Depending on embodiments, the second mask inorganic layer IOL2 may be described as the second lower inorganic layer L2 or the second upper inorganic layer U2.

According to an embodiment, the mask membrane MM may be located in line with (to correspond to or to overlap) the cell areas CA. The mask membrane MM may include a plurality of mask shadows MS and pixel openings SOP.

The pixel openings SOP may be located between adjacent ones of the mask shadows MS. The pixel openings SOP may be referred to as holes or mask holes. The plurality of pixel openings SOP may be defined or formed through the mask frame MF along the thickness direction of the mask MK (e.g., third direction (z-axis direction)). During the fabrication process, the plurality of pixel openings SOP may be formed by etching portions of the mask substrate MSUB, the first mask inorganic material layer IOL1 and the second mask inorganic material layer IOL2 from the bottom surface s2 of the mask substrate MSUB.

The mask shadows MS may surround the pixel openings SOP. The mask shadows MS may have, but is not limited to, a reverse tapered shape.

The mask shadows MS can work as a blocking unit that masks a substrate subjected to deposition (e.g., the display panel 410, or backplane substrate) when a deposition material evaporates from a deposition source inside a deposition apparatus. Accordingly, the deposition material generated from the deposition source may be deposited on a surface of the substrate subjected to deposition (e.g., the display panel 410 or backplane substrate) through the pixel openings SOP.

According to an embodiment of the disclosure, the mask shadows MS may include a same material as the second upper inorganic layer U2. In the process of fabricating the mask MK, the mask shadows MS and the second mask inorganic layer U2 may be integrally formed as a single unitary indivisible body and then formed into the shapes shown in the drawings via a subsequent etching process.

A mask conductive layer CL of the mask MK1 may entirely surround the mask frame MF and the mask shadows MS.

The mask conductive layer CL may be provided to effectively prevent mask defects, which may be caused by static electricity and physical pressure generated during the contact and separation processes between the mask MK1 and the display panel 410, from occurring.

The mask conductive layer CL may include a conductive metal material. In an embodiment, for example, the mask conductive layer CL may include, but is not limited to, at least one selected from copper (Cu), silver (Ag), palladium (Pd), aluminum (Al), tungsten (W), molybdenum (Mo), chromium (Cr), gold (Au), titanium (Ti), nickel (Ni), and neodymium (Nd). The mask conductive layer CL may include any metal having conductive properties in addition to the metals listed above.

In some embodiments, the mask conductive layer CL may include a first portion CL1, a second portion CL2, and a third portion CL3. The first portion CL1 may be located in the cell peripheral area CRA and may surround (or entirely cover) the mask frame MF. The second portion CL2 may be located in the cell areas CA and may surround (or entirely cover) the mask shadows MS. The third portion CL3 may be located in the cell peripheral area CRA and the edge area EDA and may surround (or entirely cover) the first mask inorganic layer IOL1, the second mask inorganic layer IOL2, and the mask substrate MSUB. The first portion CL1, the second portion CL2 and the third portion CL3 may be spaced apart from one another with the mask opening COP therebetween. In other words, the first portion CL1, the second portion CL2 and the third portion CL3 may be spaced apart from one another with the pixel opening SOP therebetween.

In an embodiment, the mask conductive layer CL is formed using a deposition technique such as ALD and CVD, such that the mask conductive layer CL may be formed with a uniform thickness along the profile of the underlying structure. In such an embodiment, the first portion CL1 may completely surround the mask frame MF with a uniform thickness along the profile of the mask frame MF. In addition, the second portion CL2 may completely surround the mask shadow MS with a uniform thickness along the profile of the mask shadow MS. In addition, the third portion CL3 may completely surround the first mask inorganic layer IOL1, the second mask inorganic layer IOL2 and the mask substrate MSUB along the profiles of the first mask inorganic layer IOL1, the second mask inorganic layer IOL2 and the mask substrate MSUB. More detailed descriptions thereof will be given below.

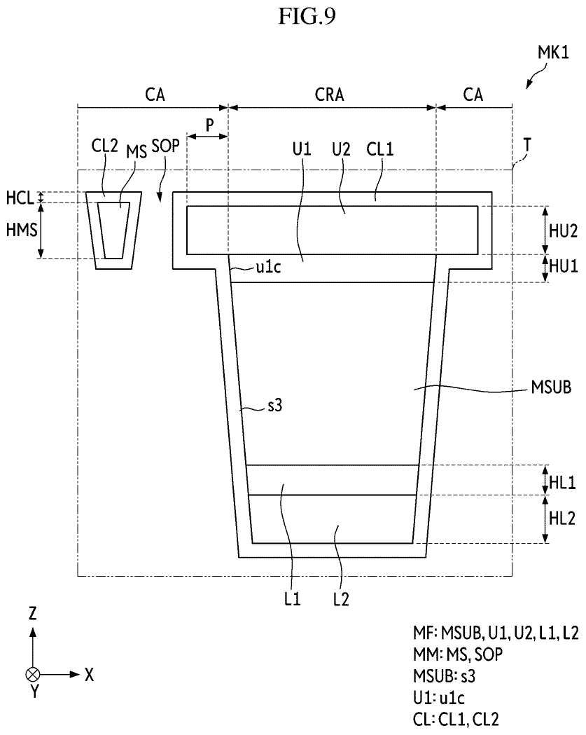

FIG. 9 is an enlarged cross-sectional view of area T of FIG. 8.

Referring to FIG. 9, the first upper inorganic layer U1 according to an embodiment of the disclosure may include a side surface ulc. The side surface ulc of the first upper inorganic layer U1 may be located on a same plane as the side surface s3 of the mask substrate MSUB.

According to an embodiment of the disclosure, a protrusion P of the second upper inorganic layer U2 may protrude toward the cell area CA more than side surface ulc of the first upper inorganic layer U1. Accordingly, an undercut (or an undercut structure) may be collectively formed or defined by the protrusion P of the second upper inorganic layer U2 and the side surface u1c of the first upper inorganic layer U1.

According to an embodiment of the disclosure, the height HU1 of the first upper inorganic layer U1 may be equal to the height HL1 of the first lower inorganic layer L1. Here, a height of a layer may mean a thickness thereof. In addition, the height HU2 of the second upper inorganic layer U2 may be equal to the height HL2 of the second lower inorganic layer L2. As described above, in the process of fabricating the mask MK1, the first upper inorganic layer U1 and the first lower inorganic layer L1 may be integrally formed as a single unitary indivisible body, and then may be formed into the shapes shown in the drawings via a subsequent process. Accordingly, the first upper inorganic layer U1 and the first lower inorganic layer L1 may include or be made of a same material as each other and have a same height as each other. In addition, in the process of fabricating the mask MK1, the second upper inorganic layer U2 and the second lower inorganic layer L2 may be integrally formed as a single unitary indivisible body, and then may be formed into the shapes shown in the drawings via a subsequent process. Accordingly, the second upper inorganic layer U2 and the second lower inorganic layer L2 may include or be made of a same material as each other and have a same height as each other.

According to an embodiment of the disclosure, the height HU2 of the second upper inorganic layer U2 may be equal to the height HMS of the mask shadows MS. As described above, in the process of fabricating the mask MK1, the second upper inorganic layer U2 and the mask shadows MS may be integrally formed as a single unitary indivisible body, and then may be formed into the shapes shown in the drawings via a subsequent process. Accordingly, the second upper inorganic layer U2 and the mask shadows MS may include or be made of a same material as each other and have a same height as each other.

In some embodiments, the height HMS of the mask shadows MS may be, but is not limited to, about 0.5 micrometers or greater and about 2.5 micrometers or less. any repetitive detailed descriptions of the same or like features as those described above will be omitted.

The first portion CL1 of the mask conductive layer CL included in the mask MK1 may entirely cover the protrusion P of the second upper inorganic layer U2, and may also entirely cover the undercut collectively formed by the protrusion P of the second upper inorganic layer U2 and the side surface ulc of the first upper inorganic layer U1. The first portion CL1 of the mask conductive layer CL may be in contact with the first upper inorganic layer U1, the second upper inorganic layer U2, the mask substrate MSUB, the first lower inorganic layer L1 and the second lower inorganic layer L1.

The second portion CL2 of the mask conductive layer CL included in the mask MK1 may completely cover the mask shadow MS and may be entirely in contact with (i.e., in contact with entire outer surfaces of) the mask shadow MS.

In some embodiments, the second portion CL2 may have, but is not limited to, a reverse taper shape as the second portion CL2 covers the profile of the mask shadow MS with a uniform thickness.

The first portion CL1 and the second portion CL2 of the mask conductive layer CL may have a same height as each other. In an embodiment, for example, the height HCL of the mask conductive layer CL may be, but is not limited to, about 20 nanometers or greater and about 300 nanometers or less.

In such an embodiment, as the mask MK1 includes the mask conductive layer CL that entirely covers the mask frame MF and the mask shadow MS, it is possible to effectively prevent mask defects, which may be caused by static electricity and physical pressure generated during the contact and separation processes between the mask MK1 and the display panel 410, from being occurring.

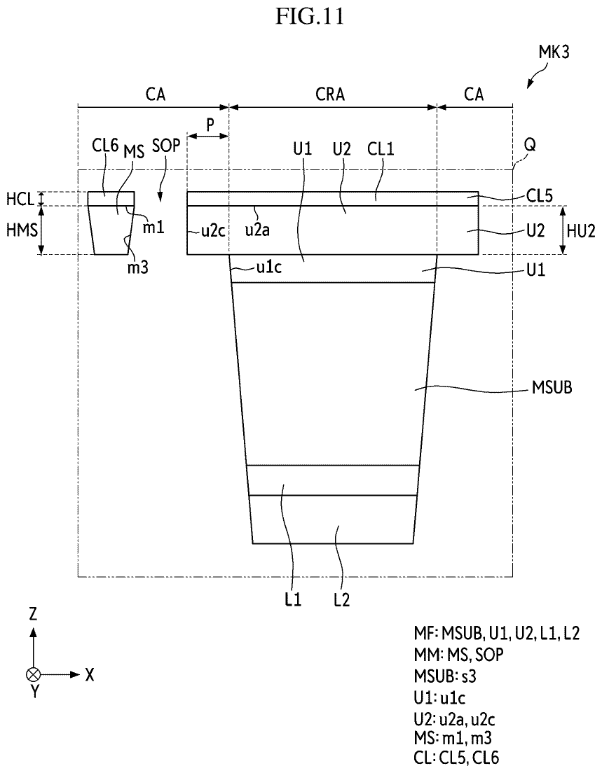

FIG. 10 is a cross-sectional view of another example, taken along line X1-X1′ of FIG. 6. FIG. 11 is an enlarged cross-sectional view of area Q of FIG. 10.

Referring to FIGS. 10 and 11, a mask conductive layer CL of an embodiment of a mask MK3 may have a different structure from the mask conductive layer CL of the embodiment of the mask MK1 described above with reference to FIGS. 8 and 9. The following description will focus on the difference between the mask MK1 and the mask MK3.

In an embodiment, the mask conductive layer CL included in the mask MK3 may include a first portion CL5, a second portion CL6, and a third portion CL7. The first portion CL1 may be located in the cell peripheral area CRA and may be located on the mask frame MF. The second portion CL6 may be located in the cell area CA and may be located on the mask shadow MS. The third portion CL7 may be located in the cell peripheral area CRA and the edge area EDA, and may be located on the second mask inorganic layer IOL2. The first portion CL5, the second portion CL6 and the third portion CL7 may be spaced apart from one another with the mask opening COP therebetween. In other words, the first portion CL5, the second portion CL6 and the third portion CL7 may be spaced apart from one another with the pixel opening SOP therebetween.

In some embodiments, the second upper inorganic layer U2 of the mask MK3 may have a top surface u2a and a side surface u2c. The top surface u2a may face the mask conductive layer CL, and the side surface u2c may face the mask shadow MS. The side surface u2c of the second upper inorganic layer U2 may protrude toward the cell area CA more than the side surface ulc of a first upper inorganic layer U1. In other words, the side surface u2c of the second upper inorganic layer U2 may overlap the protrusion P of the second upper inorganic layer U2. The side surface u2c of the second mask inorganic layer U2 may be spaced apart from the mask shadows MS with the pixel opening SOP therebetween.

The first portion CL5 of the mask conductive layer CL may be located on the upper surface u2a of the second upper inorganic layer U2 and may be in contact with the upper surface u2a. The first portion CL5 may entirely cover the upper surface u2a of the second upper inorganic layer U2. The first portion CL5 may overlap the protrusion P of the second upper inorganic layer U2 in the third direction (Z-axis direction).

In some embodiments, the first portion CL5 of the mask MK3 may not be in contact with a first upper inorganic layer U1, a mask substrate MSUB, a first lower inorganic layer L1, or a second lower inorganic layer L2. In addition, the first portion CL5 may not be in contact with the side surface u2c of the second upper inorganic layer U2, but the disclosure is not limited thereto.

In some embodiments, the mask shadow MS of the mask MK3 may have a top surface m1 and a side surface m3. The top surface m1 of the mask shadow MS may face the mask conductive layer CL, and the side surface m3 may face the pixel opening SOP.

The second portion CL6 of the mask conductive layer CL may be located on the upper surface m1 of the mask shadow MS and may be in contact with the upper surface m1. The second portion CL6 may entirely cover the upper surface m1 of the mask shadow MS.

In some embodiments, the second portion CL6 of the mask MK3 may be not in contact with the side surface u2c of the mask shadow MS, but the disclosure is not limited thereto.

According to some embodiments, the height HU2 of the second upper inorganic layer U2 may be equal to the height HMS of the mask shadows MS. The height HMS of the mask shadows MS may be, but is not limited to, about 0.5 micrometers or greater and about 2.5 micrometers or less.

In the cell peripheral area CRA and the edge area EDA, the third portion CL7 of the mask conductive layer CL may be in contact with the second mask inorganic layer IOL2 and may entirely cover the upper surface of the second mask inorganic layer IOL2.

The first portion CL5, the second portion CL6 and the third portion CL7 of the mask conductive layer CL may have a same height as each other. In an embodiment, for example, the height HCL of the mask conductive layer CL may be, but is not limited to, about 20 nanometers or greater and about 300 nanometers or less. any repetitive detailed descriptions of the same or like features as those described above will be omitted.

In an embodiment, as the mask MK3 includes the mask conductive layer CL on the second upper inorganic layer U2 and the mask shadow MS, it is possible to effectively prevent mask defects, which may be caused by static electricity and physical pressure generated during the contact and separation processes between the mask MK3 and the display panel 410, from being occurring.

Although the embodiments of the disclosure have been described with reference to the accompanying drawings, those skilled in the art would understand that various modifications and alterations may be made without departing from the technical idea or essential features of the present disclosure. Therefore, it should be understood that the above-mentioned embodiments are not limiting but illustrative in all aspects.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate comprising a plurality of cell areas and a cell peripheral area surrounding the cell areas;
a mask membrane disposed in the cell areas of the mask substrate and comprising a mask shadow defining a pixel opening;
a mask frame disposed in the cell peripheral area of the mask substrate and comprising a first upper inorganic layer located on the mask substrate and a second upper inorganic layer located on the first upper inorganic layer; and
a mask conductive layer comprising a first portion located on the mask frame and a second portion located on the mask shadow,
wherein the first portion and the second portion are spaced apart from each other with the pixel opening therebetween.

2. The deposition mask of claim 1, wherein a height of the mask conductive layer is equal to or greater than about 20 nanometers and equal to or less than about 300 nanometers.

3. The deposition mask of claim 2, wherein the mask conductive layer comprises a conductive metal material.

4. The deposition mask of claim 1, wherein the first portion completely surrounds the mask frame, and
wherein the second portion of the mask conductive layer completely surrounds the mask shadow.

5. The deposition mask of claim 4, wherein the second upper inorganic layer comprises a protrusion that protrudes toward the cell areas than a side surface of the first upper inorganic layer, and
wherein the first portion overlaps the protrusion of the second upper inorganic layer in a thickness direction of the mask substrate.

6. The deposition mask of claim 5, wherein the side surface of the first upper inorganic layer and the protrusion of the second upper inorganic layer collectively form an undercut.

7. The deposition mask of claim 6, wherein the first portion entirely covers the undercut.

8. The deposition mask of claim 4, wherein the first portion is in contact with the mask substrate, the first upper inorganic layer, and the second upper inorganic layer.

9. The deposition mask of claim 8, wherein the second portion is entirely in contact with the mask shadow.

10. The deposition mask of claim 4, wherein the mask frame further comprises:
a first lower inorganic layer located on an opposite side of the mask substrate to the first upper inorganic layer; and
a second lower inorganic layer located on the first lower inorganic layer, and
wherein the mask conductive layer is in contact with the first lower inorganic layer and the second lower inorganic layer.

11. The deposition mask of claim 10, wherein the first upper inorganic layer and the first lower inorganic layer comprise a same material as each other, and
wherein the second upper inorganic layer and the second lower inorganic layer comprise a same material as each other.

12. The deposition mask of claim 1, wherein the mask shadow comprises a same material as the second upper inorganic layer.

13. The deposition mask of claim 12, wherein a height of the mask shadow is equal to or greater than about 0.5 micrometers and equal to or less than about 2.5 micrometers.

14. The deposition mask of claim 1, wherein the mask substrate further comprises an edge surface including an edge of the mask substrate, and
wherein the mask conductive layer further comprises a third portion overlapping the edge surface.

15. The deposition mask of claim 14, wherein the third portion is spaced apart from the second portion with the pixel opening therebetween.

16. The deposition mask of claim 1, wherein the mask shadow completely surrounds the pixel opening in a plan view, and
wherein the mask frame completely surrounds the mask membrane in the plan view.

17. The deposition mask of claim 1, wherein the mask substrate comprises silicon, and
wherein the mask substrate has a circular shape in a plan view.

18. The deposition mask of claim 1, wherein the second upper inorganic layer comprises a first surface located on an opposite side, which is opposite to a side thereof facing the first upper inorganic layer, and
wherein the first portion is entirely in contact with the first surface of the second upper inorganic layer.

19. The deposition mask of claim 18, wherein the first portion is in contact neither with the first upper inorganic layer nor with the mask substrate.

20. The deposition mask of claim 19, wherein the mask shadow comprises a second surface facing the mask conductive layer,
wherein the second portion is entirely in contact with the second surface of the mask shadow, and
wherein the second portion is not in contact with a side surface of the mask shadow facing the pixel opening.

21. An electronic device comprising:
A display device including a display panel formed using a deposition mask;
a mask substrate comprising a plurality of cell areas and a cell peripheral area surrounding the cell areas;
a mask membrane disposed in the cell areas of the mask substrate and comprising a mask shadow defining a pixel opening;
a mask frame disposed in the cell peripheral area of the mask substrate and comprising a first upper inorganic layer located on the mask substrate and a second upper inorganic layer located on the first upper inorganic layer; and
a mask conductive layer comprising a first portion located on the mask frame and a second portion located on the mask shadow,
wherein the first portion and the second portion are spaced apart from each other with the pixel opening therebetween.
